(19) United States
(12) Patent Application Publication
(10) Pub. No.: US 2015/0310901 A1
(43) Pub. Date: Oct. 29, 2015

(54) MEMORY WITH A SLEEP MODE

(71) Applicant: QUALCOMM INCORPORATED, San Diego, CA (US)

(72) Inventors: Changho Jung, San Diego, CA (US); Rakesh Vattikonda, San Diego, CA (US); Tony Chung Yiu Kwok, San Diego, CA (US)

(73) Assignee: QUALCOMM INCORPORATED, San Diego, CA (US)

(21) Appl. No.: 14/261,192

(22) Filed: Apr. 24, 2014

(51) Int. Cl. G11C 7/12; G11C 5/14

(52) U.S. Cl. CPC G11C 7/12; G11C 5/148

(57) ABSTRACT

A memory and a method for operating the memory having a sleep mode are provided. The memory one or more storage elements and a bitline coupled to the one or more storage elements. A precharge circuit is configured to precharge the bitline during a precharge period and float the bitline during a sleep mode. An operating circuit coupled to the one or more storage elements, wherein at least one of the operating circuit and the one or more storage elements being configured to remain electrically coupled to a supply voltage in the sleep mode.

### BACKGROUND

1. Field

The present disclosure relates generally to electronic circuits, and more particularly, a memory with a sleep mode.

2. Background

With the ever increasing demand for more processing capability in mobile devices, low power consumption has become a common design requirement. Various techniques are currently being employed to reduce power consumption in such devices. One example of such technique is a sleep mode in which all power supplies to a memory are disconnected. As a result, the memory operating in such sleep mode would draw no power.

### SUMMARY

Aspects of a memory are disclosed. The memory includes one or more storage elements. A bitline is coupled to the one or more storage elements. A precharge circuit configured to precharge the bitline during a precharge period and float the bitline during the sleep mode. A operating circuit is configured operate a part of the memory and is configured to remain electrically coupled to a supply voltage in the sleep mode.

Further aspects of a memory are disclosed. The memory includes a bitline and one or more storage means for storing a value. The one or more storage means are coupled to the bitline. The memory includes precharging means for precharging the bitline during a precharge period and floating the bitline during the sleep mode. Operating means for operating a part of the memory is configured to remain electrically coupled to a supply voltage in the sleep mode.

Aspects of a method for operating a memory are disclosed. The method includes precharging a bitline during a precharge period. The bitline is coupled to one or more storage elements. The method further includes entering a sleep mode and floating the bitline. An operating circuit configured to operate a part of the memory remains electrically coupled to a supply voltage in the sleep mode.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1 is a block diagram illustrating an exemplary embodiment of a memory.

FIG. 2 is a block diagram illustrating an embedded application of an exemplary embodiment.

FIG. 3 is a schematic representation of an exemplary embodiment of a bitcell for an SRAM.

FIG. 4 is a functional block diagram of an exemplary embodiment of an SRAM.

FIG. 5 is a schematic diagram of various portions of an exemplary embodiment of a memory having a sleep mode.

FIG. 6 is a diagram illustrating the operation states of a memory access of an exemplary embodiment.

FIG. 7 is a flowchart of the operations of a memory having a sleep mode

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

Various apparatus and methods presented throughout this disclosure may be implemented in various forms of hardware. By way of example, any of these apparatus or methods, either alone or in combination, may be implemented as an integrated circuit, or as part of an integrated circuit. The integrated circuit may be an end product, such as a microprocessor, a digital signal processor (DSP), an application specific integrated circuit (ASIC), programmable logic, or any other suitable integrated circuit. Alternatively, the integrated circuit may be integrated with other chips, discrete circuit elements, and/or other components as part of either an intermediate product, such as a motherboard, or an end product. The end product can be any suitable product that includes integrated circuits, including by way of example, a cellular phone, personal digital assistant (PDA), laptop computer, a desktop computer (PC), a computer peripheral device, a multimedia device, a video device, an audio device, a global positioning system (GPS), a wireless sensor, or any other suitable device.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of the stated features, integers, steps, operations, elements, and/or components, but do not preclude the presence or addition of one or more other features, integers, steps, operations, elements, components, and/or groups thereof.

Various aspects of a memory on an integrated circuit (IC) having a novel sleep mode will now be presented. Such IC may be, for example, a system-on-chip (SOC) processor for a communication apparatus (such as mobile phone). However, as those skilled in the art will readily appreciate, such aspects may be extended to other circuit configurations. Accordingly, all references to a specific application for a memory is intended only to illustrate exemplary aspects of the memory with the understanding that such aspects may have a wide differential of applications.

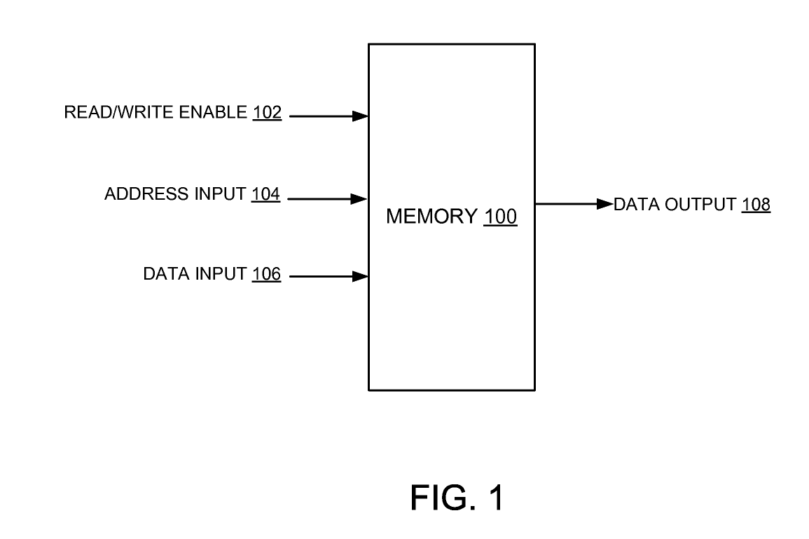

FIG. 1 is a block diagram illustrating an exemplary embodiment of a memory. The memory 100 provides a medium for peripheral circuits to write and read program instructions and data. As used hereinafter, the term “data” will be understood to include program instructions, data, and any other information that may be stored in the memory 100. The memory 100 includes a read/write enable 102 for controlling the read/write operation of the memory 100. The memory 100 also includes an address input 104, a data input 106 for writing data to the memory 100 at the specified address, and a data output 108 for reading data from the memory 100 at the specified address. When writing data to the memory 100, a peripheral circuit sets the read/write enable to the write mode and sends to the memory 100 the address along with the data to be written to the memory 102 at that address. When reading data from the memory 100, the peripheral circuit sets the read/write enable to the read mode and sends the address to the memory 100. In response, the memory 100 sends data at that address to the peripheral circuit.

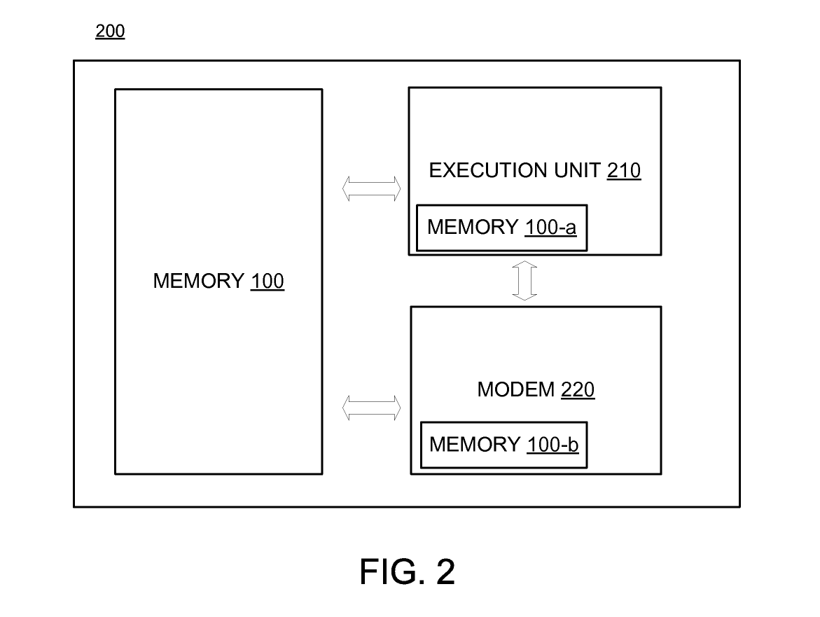

FIG. 2 is a block diagram illustrating an embedded application of an exemplary embodiment. The memory 100 may be a discrete memory on its own substrate or be utilized for embedded applications. FIG. 2 illustrates an example of a system-on-chip processor 200. The processor 200 may be a processor for a cell phone and includes an execution unit 210 and a modem 220 (which handles the communication functions of the cell phone). The memory 100 may function as a cache memory for the processor 200 or be used for any storage needs. The memory 100 may be formed on a same substrate as the execution unit 210 and the modem 220. The memory 100 may also be on its own substrate and packaged with processor 200 by a substrate-on-substrate assembly. Moreover, a memory 100-a may be integrated as part of the execution unit 210 and may function as, e.g., a register file for the execution unit 210. A memory 100-b may likewise be integrated as part of the modem 220.

The memory 100 may be any suitable storage medium, such as, by way of example, a static random access memory (SRAM). SRAM is volatile memory that requires power to retain data. However, as those skilled in the art will readily appreciate, the memory 102 is not necessarily limited to SRAM. Accordingly, any reference to SRAM is intended only to illustrate various concepts, with the understanding that such concepts may be extended to other memories.

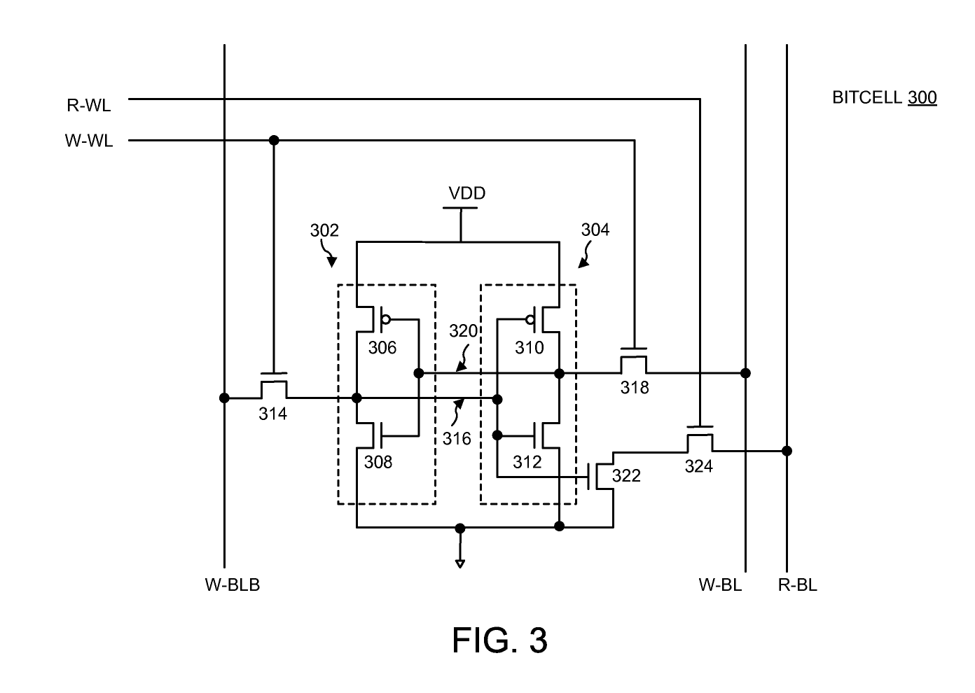

SRAM includes an array of storage elements know as “bitcells.” Each bitcell is configured to store one bit of data. FIG. 3 is a schematic representation of an exemplary embodiment of a bitcell for an SRAM. The bitcell is implemented with an eight-transistor (8T) configuration. However, as those skilled in the art will readily appreciate, the bitcell may be implemented with a four-transistor (4T), six-transistor (6T), ten-transistor (10T) configuration, or any other suitable transistor configuration.

The bitcell 300 is shown with two inverters 302, 304. The first inverter 302 comprises a P-channel transistor 306 and an N-channel transistor 308. The second inverter 304 comprises a P-channel transistor 310 and an N-channel transistor 312. The first and second inverters 302, 304 are interconnected to form a cross-coupled latch. A first N-channel write access transistor 314 couples the output 316 from the first inverter 302 to a first local write bitline W-BLB and a second N-channel write access transistor 318 couples the output 320 from the second inverter 304 to a second local write bitline W-BL. The gates of the N-channel write access transistors 314, 318 are coupled to a write wordline W-WL. The output 316 from the first inverter 302 is also coupled to the gate of an N-channel transistor 322. An N-channel read access transistor 324 couples the output from the N-channel transistor 322 to a local read bitline R-BL. The gate of the N-channel read access transistor 324 is coupled to a read wordline R-WL.

The write operation is initiated by setting the local write bitlines W-BLB, W-BL to the value to be written to bitcell 300 and then asserting the write wordline W-WL. By way of example, a logic level 1 may be written to the bitcell 300 by setting the first local write bitline BLB to a logic level 0 and the second local write bitline BL to a logic level 1. The logic level 0 at the first local write bitline W-BLB is applied to the input of the second inverter 304 through the write access transistor 314, which in turn forces the output 320 of the second inverter 304 to a logic level 1. The output 320 of the second inverter 304 is applied to the input of the first inverter 302, which in turn forces the output 316 of the first inverter 302 to a logic level 0. A logic level 0 may be written to the bitcell 300 by inverting the values of the local write bitlines W-BLB, W-BL. The local write bitline drivers (not shown) are designed to be much stronger than the transistors in the bitcell 300 so that they can override the previous state of the cross-coupled inverters 302, 304.

The read operation is initiated by precharging the local read bitline R-BL to a logic level 1 and then asserting the read wordline R-WL. With the read wordline asserted, the output from the N-channel transistor 322 is transferred to the local read bitline R-BL through the read access transistor 324. By way of example, if the value stored at the output 320 of the second inverter 304 is a logic level 0, the output 316 from the first inverter 302 forces the N-channel transistor 322 on, which in turn causes the local read bitline R-BL to discharge to a logic level 0 through the read access transistor 324 and the N-channel transistor 322. If the value stored at the output 320 of the second inverter 304 is a logic level 1, the output 316 from the first inverter 302 forces the N-channel transistor 322 off As a result, the local read bitline R-BL remains charged to a logic level 1.

When the SRAM is in a standby mode, the write wordline W-WL and read wordline R-WL are set to a logic level 0. The logic level 0 causes the write access transistors 314, 318 and the read access transistor 324 to disconnect the local write and read bitlines W-BL, W-BLB, R-BL from the two inverters 302, 304. The cross-coupling between the two inverters 302, 304 maintains the state of the output as long as power is applied to the bitcell 300.

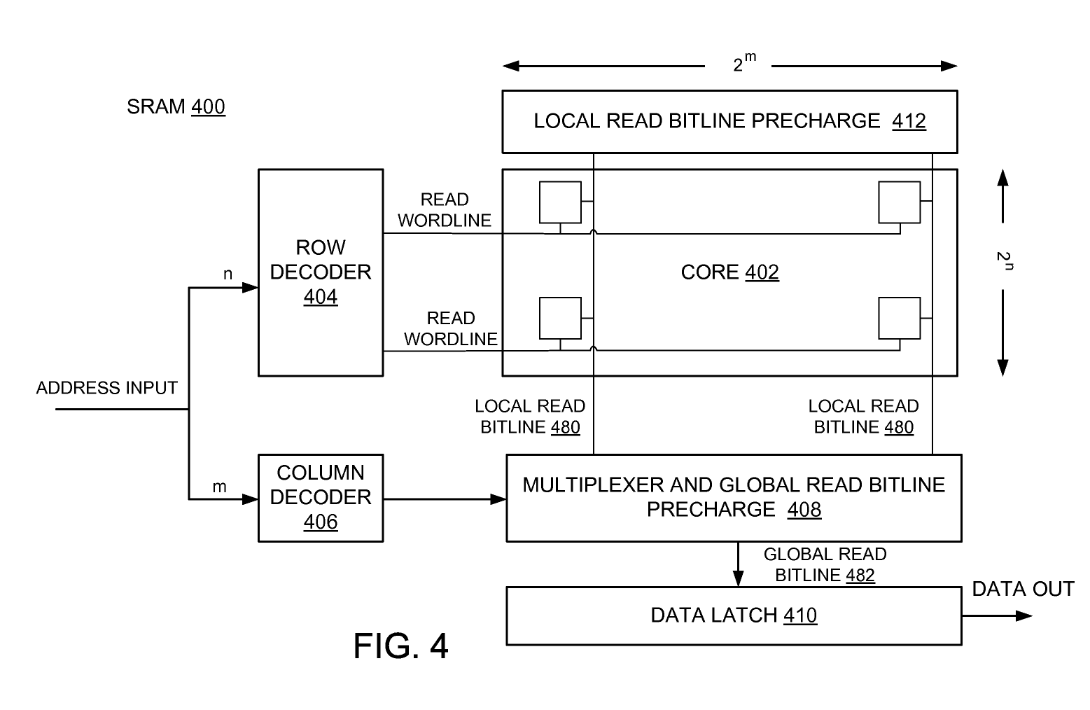

FIG. 4 is a functional block diagram of an exemplary embodiment of an SRAM. Various aspects of an SRAM will now be presented in the context of a read operation. Accordingly, for clarity of presentation, only the connections for the read operation are shown. Those skilled in the art will readily appreciate that additional connections are required to support the write operation.

The SRAM 400 includes a memory core 402 with supporting circuitry to decode addresses and perform read and write operations. The memory core 402 is comprised of bitcells arranged to share connections in horizontal rows and vertical columns. Specifically, each horizontal row of bitcells shares a read wordline and each vertical column of bitcells shares a local read bitline. The size of the memory core 402 (i.e., the number of bitcells) may vary depending on a variety of factors including the specific application, the speed requirements, the layout and testing requirements, and the overall design constraints imposed on the system. Typically, the memory core 402 will contain thousands or millions of bitcells.

In the exemplary embodiment of the SRAM shown in FIG. 4, the memory core 402 is made up of (2ⁿ×2^{m}) bitcells arranged in 2ⁿ horizontal rows and 2^{m} vertical columns. A peripheral device (not shown) may randomly access any bitcell in the memory core 402 using an address that is (n+m) bits wide. In this example, n-bits of the address are provided to the input of a row decoder 404 and m-bits of the address are provided to the input of a column decoder 406. The SRAM 400 is placed into a read mode by the read/write enable signal (not shown). The read/write enable signal causes, among other things, the precharging of the local read bitlines by the local read bitline precharge 412.

The row decoder 404 converts the n-bit address into 2ⁿ read wordline outputs. A different read wordline is asserted by the row decoder 404 for each different n-bit row address. As a result, each of the 2^{m} bitcells in the horizontal row with the asserted read wordline is connected to one of the 2^{m} local read bitlines 480 through its access transistor as described above in connection with FIG. 3. The 2^{m} local read bitlines 480 are used to transmit the bits stored by the m bitcells to a multiplexer that selects one or more bits from the 2ⁿ bits transmitted on the local read bitlines 480. The number of bits that are selected by the multiplexer is based on the width of the SRAM output. By way of example, the multiplexer may select 64 of the 2^{m} bits to support an SRAM having a 64-bit output. In the described exemplary embodiment, the multiplexer selects one of the 2^{m} bits. The selected bit may be referred to as a global read bitline 482.

The multiplexer and global read bitline precharge 408 includes the circuits to perform the multiplexing or selecting function described above. The multiplexer and global read bitline precharge 408 further includes circuits that precharge the global read bitline 482 for the read operation. The global read bitline 482 output from the multiplexer and global read bitline precharge 408 is provided to a data latch 410 for further processing before being output to a peripheral circuit (not shown). In one example, the data latch 410 provides the data from the global read bitline 482 to the execution unit 210 or the modem 220.

A sleep mode in which the memory is electrically decoupled from all power supplies is known as a deep sleep mode. The deep sleep mode is advantageous in that the memory consumes no power in such mode. However, activating the memory for an access from the deep sleep mode may require substantial delays (e.g., additional wait delays may need to be added intentionally after exiting the deep sleep mode).

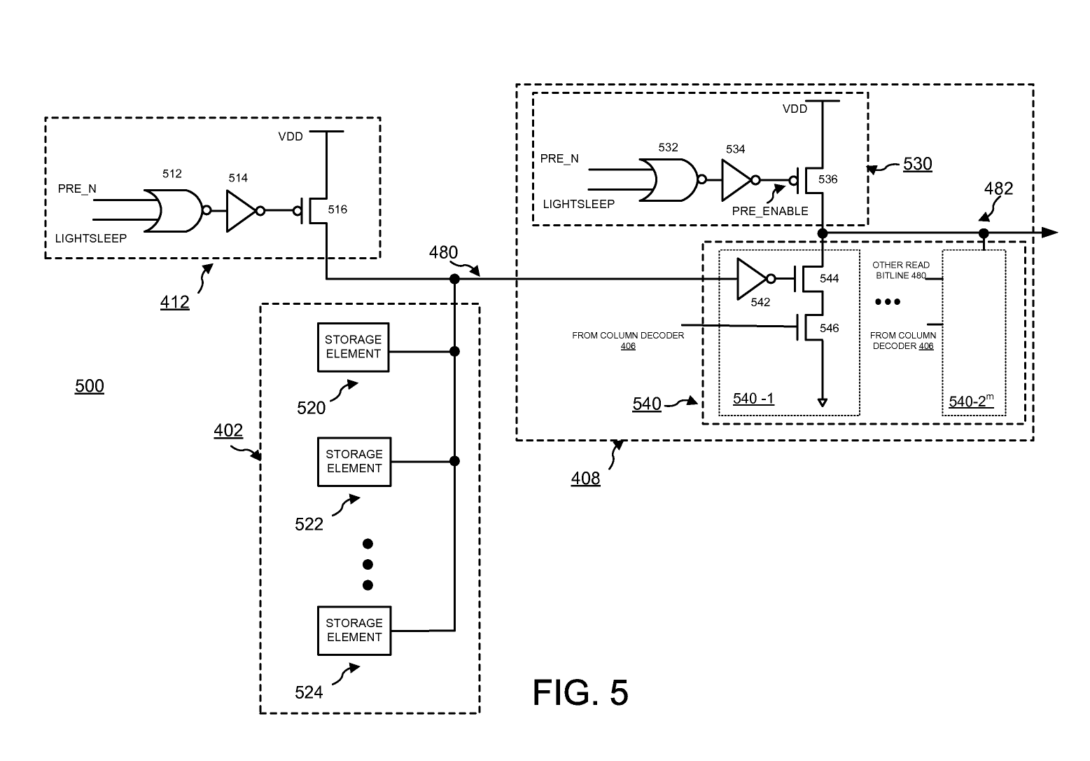

FIG. 5 is a schematic diagram 500 illustrating various portions of an exemplary embodiment of a memory. The exemplary embodiment includes a sleep mode which reduces power consumption and requires no delay when exiting the sleep mode. This sleep mode may also be referred to as light sleep mode to differentiate it from the deep sleep mode. In the exemplary embodiment, the bitlines (local or global) are electrically decoupled from the supply voltage (e.g., VDD). The bitlines are floating in the sleep mode and therefore, draw no power in the period. In one example, the bitlines are not electrically coupled to any supply voltage and ground. For example, circuits such as the row decoder 404, column decoder 406, data latch 410, control circuits and other portions of the memory are coupled to the memory core 402 and configured to or providing the means to operate the memory. Any of these circuits configured to operate or to provide the means to operate the memory may be electrically coupled to a voltage supply in the sleep mode. Alternatively, the memory core 402 and the storage elements therein may remain electrically coupled to the voltage supply in the sleep mode. In one configuration of the memory, only the bitlines float (and not the memory core 402 and any of the operating circuit) in the sleep mode. In another configuration of the memory, all bitlines in the memory are configured to float in the sleep mode.

Thus, at least one portion of the memory (e.g., one of a control circuit and the storage elements) remains electrically coupled to the supply voltage in the sleep mode. The portions of the memory remaining electrically coupled to the supply voltage in the sleep mode are configured such that, in response to an end of the sleep mode, the memory may enter the subsequent memory access with no delay. In one example, there are no wait delays added between the exiting of the sleep mode and the start of the subsequent memory access (e.g., the precharge period of the subsequent memory access). As would be understood by one of ordinary skill in the art, the supply voltage may be read broadly for supplying a plurality of voltage levels.

As illustrated, the memory core 402 includes a plurality of storage elements (520, 522, or 524, etc.) coupled to the read wordline R-WL and coupled to the local read bitline 480. The storage elements may be examples of the memory bitcells and provide the means for storing a value. A storage element may be, for example, an SRAM or other type of memory cell that stores a value (e.g., a value that may be read as a logic “1” or a logic “0”). Accordingly, the local read bitline 480 is directly coupled to at least one storage element (520, 522, or 524, etc.) at least because the coupling is not via another bitline.

A read memory access of the memory may start with a precharge operation in a precharge period, in which the bitlines (such as the local read bitline 480 or the global read bitline 482) are precharged or pulled-up to, e.g., VDD level. A read operation may follow the precharge operation and outputs the stored value onto the global read bitline 482 based on the stored value of a storage element (520, 522, or 524, etc.). In one example, the valued is outputted onto the global read bitline 482 via the local read bitline 480. First, the read wordline R-WL goes high to select a storage element (520, 522, or 524, etc.). The selected storage element (520, 522, or 524, etc.) may selectively output a value onto the local read bitline 480 based on its stored value. As illustrated in FIG. 3, a memory bitcell 300 may include an N-channel transistor 322 which functions as a pull-down circuit in the read operation and selectively pulls down the local read bitline 480 based on the stored value of the storage element. The local read bitline 480 then may pull down the global read bitline 482, thereby coupling the stored value onto the global read bitline 482. Accordingly, the global read bitline 482 is indirectly coupled to at least one storage elements (520, 522, or 524, etc.) at least because the coupling is via another bitline (local read bitline 480).

The local read bitline 480 is precharged by the local read bitline precharge circuit 412 to VDD level (e.g., in a precharge period prior to the read operation). In the exemplary embodiment, the local read bitline precharge 412 receives a precharge trigger PRE_N and the sleep mode signal LIGHTSLEEP. When the memory of the exemplary embodiment is not in the sleep mode (i.e., LIGHTSLEEP is low), the precharge trigger PRE_N goes low to initiate the precharging of the local read bitline 480. The precharge trigger PRE_N going low turns on the P-channel MOS precharge transistor 516 (e.g., the pull up device), which is coupled to a supply voltage VDD and precharges or pulls up the local read bitline 480 to VDD level. Accordingly, in the exemplary embodiment, the precharge transistor 516 provides the means to precharge or pull up the local read bitline 480 during the precharge period.

When the memory of the exemplary embodiment enters the sleep mode, the sleep mode signal LIGHTSLEEP goes high, and in response, the logic elements of the local read bitline precharge circuit 412 disable the precharge trigger PRE_N from being provided to the pull up device (e.g., the precharge transistor 516) during the sleep mode.

In other words, the logic elements of the local read bitline precharge circuit 412 are configured to remove the precharge trigger PRE_N from the pull up device (e.g., the precharge transistor 516) during the sleep mode. The precharge circuit (e.g., precharge transistor 516) is deactivated during the sleep mode. As illustrated in FIG. 5, the local read bitline precharge circuit 412 includes logic elements for performing the functions described above. The logic elements include a NOR gate 512 and an inverter 514, and via which OR the precharge trigger PRE_N and the sleep mode signal LIGHTSLEEP. The result of the OR and inverter operations is provided to the gate of the precharge transistor 516. Thus, the logic elements provide the means to disable the precharge trigger PRE_N from being provided to the pull up device (e.g., precharge transistor 516) during the sleep mode. Likewise, the logic means provides the means to OR the precharge trigger PRE_N with the sleep mode signal LIGHTSLEEP and provides the result to the gate of the p-channel precharge transistor 516.

Accordingly, the precharge transistor 516 is kept in the off state, and the memory does not enter precharge mode (e.g., the precharge transistor 516 does not precharge or pull up the local read bitline 480) regardless of the state of the precharge trigger PRE_N. Thus, the precharge circuit (e.g., the precharge transistor 516) is deactivated in the precharge period and does not precharge or pull up the local read bitline 480. In one example, the precharge trigger PRE_N may continue to operate (going into low state) in the sleep mode.

In the exemplary embodiment, deactivating the precharge circuit (e.g., precharge transistor 516) floats the local read bitline 480 in the sleep mode. That is, the local read bitline 480 is not electrically coupled to any supply voltage or ground in the sleep mode.

The local read bitline 480 is provided to the multiplexer and global read bitline precharge circuit 408 and via which couples to the global read bitline 482. The multiplexer and global read bitline precharge circuit 408 includes a multiplexer portion 540 and a global read bitline precharge portion 530. The multiplexer portion 540 performs the multiplexing function, e.g., selecting a local read bitline 480 from a plurality of local read bitlines and coupling the selected local read bitline 480 to the global read bitline 482. As such, the multiplexer portion 540 may be implemented using various circuits known by one of ordinary skill in the art. For example, the multiplexer function may be implemented using pass gates. In the exemplary embodiment, the multiplexer portion 540 includes multiplexed pull-down circuits 540-1 to 540-2^{m}. The multiplexer portion 540 performs the multiplexing or selecting function by way of selectively pulling down (e.g., via the pull-down transistor 544 and the selection transistor 546) one of the multiplexed pull-down circuits 540-1 to 540-2^{m}. The selection is performed by signals from the column decoder 406. Each of the pull-down circuits 540-1 to 540-2^{m} receives a different read bitline 480 and is controlled by an associated signal from the column decoder 406.

The global read bitline 482 is precharged or pulled up to VDD level by the global read bitline precharge circuit 530 (e.g., in the precharge operation prior to the read operation). The local read bitline 480 couples to the global read bitline 482 via the inverter 542 and the pull-down transistor 544. The pull-down transistor 544 is selected by the selection transistor 546. A plurality of such pull-down circuits is coupled in parallel to the global read bitline 482. In a read operation of the exemplary embodiment, the value stored in the selected storage element (520, 522, or 524, etc.) is coupled to the local read bitline 480 (e.g., the selected storage element selectively pulling down the local read bitline 480 based on the stored value). The local read bitline 480 is then selectively coupled to the global read bitline 482. For example, only one of the selection transistors is selectively turned on, allowing only the associated local read bitline 480 to pull down or couple to the global read bitline 482 via the pull-down transistor 544. In the exemplary embodiment, the selection transistor 546 is controlled by signals from the column decoder 406 to perform the multiplexing or selection function.

In the exemplary embodiment, the global read bitline precharge circuit 530 receives the precharge trigger PRE_N and the sleep mode signal LIGHTSLEEP. When the memory of the exemplary embodiment is not in the sleep mode (i.e., LIGHTSLEEP is low), the precharge trigger PRE_N goes low to initiate the precharging of the global read bitline 482. The precharge trigger PRE_N going low turns on the P-channel MOS precharge transistor (e.g., the pull up device) 536, which is coupled to a supply voltage VDD and precharges or pulls up the global read bitline 482 to VDD level. Accordingly, in the exemplary embodiment, the precharge transistor 536 provides the means to precharge or pull up the global read bitline 482.

When the memory of the exemplary embodiment enters the sleep mode, the sleep mode signal LIGHTSLEEP goes high. The sleep mode signal LIGHTSLEEP going high keeps the precharge transistor 536 in the off state, and therefore, the memory does not enter precharge mode (e.g., the precharge transistor 536 does not precharge or pull up the global read bitline 482) regardless of the state of the precharge trigger PRE_N. Thus, the precharge circuit (e.g., the precharge transistor 536) is deactivated in the precharge period and does not precharge or pull up the global read bitline 482. Accordingly, in the exemplary embodiment, the precharge transistor 536 provides the means to float the global read bitline 482. In one example, the precharge trigger PRE_N may continue to operate (going into low state) in the sleep mode.

In the exemplary embodiment, deactivating the precharge circuit (e.g., precharge transistor 536) floats the global read bitline 482 in the sleep mode. That is, the global read bitline 482 is not electrically coupled to any supply voltage or ground in the sleep mode.

As illustrated in FIG. 5, the global read bitline precharge circuit 530 includes logic elements for performing the functions described above. The logic elements include a NOR gate 532 and an inverter 534, and via which OR the precharge trigger PRE_N and the sleep mode signal LIGHTSLEEP. The result of the OR operation and the inverter is provided to the gate, PRE_ENABLE, of the precharge transistor 536. Accordingly, in the sleep mode, the sleep mode signal LIGHTSLEEP is high and the result of the OR operation (at PRE_ENABLE) is also high, keeping the precharge transistor 536 in the off state. Thus, the logic elements provide the means to disable the precharge trigger PRE_N from being provided to the pull up device (e.g., precharge transistor 536) during the sleep mode. In other words, the logic elements provides the means for removing the precharge trigger from the pull up device during the sleep mode. Likewise, the logic elements provide the means to OR the precharge trigger PRE_N with the sleep mode signal LIGHTSLEEP, invert the result, and provide the inverted result to the gate of the p-channel precharge transistor 536.

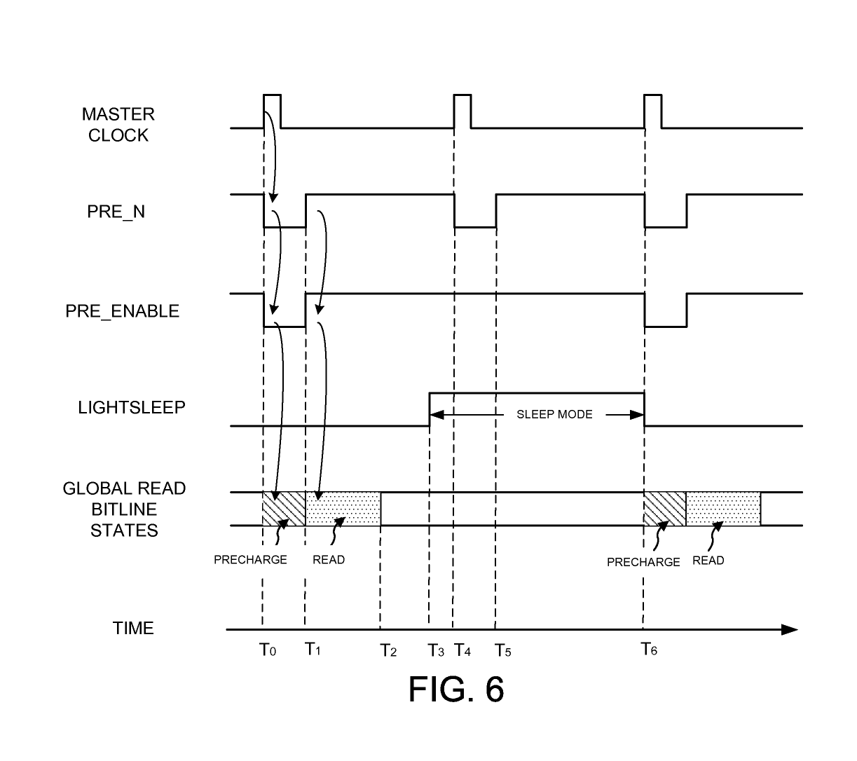

FIG. 6 is a diagram illustrating the operation states of a memory access of an exemplary embodiment. For illustrative purpose, the global read bitline states in a read memory access are provided, but the scope of the current disclosure is not limited thereto. At T₀-T₁, the memory is in the precharge period. AT T₀, the master clock goes high to trigger the read memory access. The master clock may be, e.g., the read/write enable signal described above. In response, the precharge trigger PRE_N goes low for a predetermined period of time by, e.g., the operation of a pulse latch in accordance with the knowledge of one of ordinary skill in the art. The predetermined period of the precharge trigger PRE_N in the low state may correspond to the precharge period. Because the memory is not in the sleep mode (the sleep mode signal LIGHTSLEEP is in the low state), the precharge trigger PRE_N controls the gate PRE_ENABLE of the precharge transistors 516 and 536. The PRE_ENABLE follows the precharge trigger PRE_N going into the low state and turns on the precharge transistors 516 and 536, as described with FIG. 5. Accordingly, the memory initiates the precharge operation, and the precharge transistors 516 and 536 precharge or pulls up the local read bitlines 480 and the global read bitline 482 to VDD level.

At T₁, the precharge trigger PRE_N and the PRE_ENABLE go to a high state, and the memory exits the precharge operation. Subsequently, the memory starts the read operation by, e.g., selectively pulling down the local read bitline 480 based on the stored value of the selected storage element (520, 522, or 524, etc.). The local read bitline 480 may further selectively pull down the global read bitline 482 based the operation of the multiplexer portion 540 (which is controlled by the column decoder 406). At T₂, the read memory access is completed.

At T₃, the sleep mode signal LIGHTSLEEP goes to a high state, and the memory enters the sleep mode. As a result, the PRE_ENABLE is driven high and disables the precharge transistors 516 and 536. The local read bitlines 480 and global read bitline 482 are thus electrically decoupled from the supply voltage VDD, and are floating while in the sleep mode. At T₄-T₅, the precharge trigger PRE_N continues to operate during the sleep mode (going to the active low state at T₄). As described with FIG. 5, the logic elements of circuit 412 and the global read bitline precharge circuit 530 disable the precharge trigger PRE_N from being provided to the pull up devices (precharge transistors 516 and 536) during the sleep mode. Thus, the memory does not enter into the precharge mode.

At T₆, the sleep mode signal LIGHTSLEEP goes to a low state, and the memory exits the sleep mode. The memory is in a ready state for the next memory access, which may start with no wait delay. For example, no wait or delay states are needed before the subsequent memory access (starting the precharge period for the subsequent memory access) starts at T₆, in response to the end of the sleep mode.

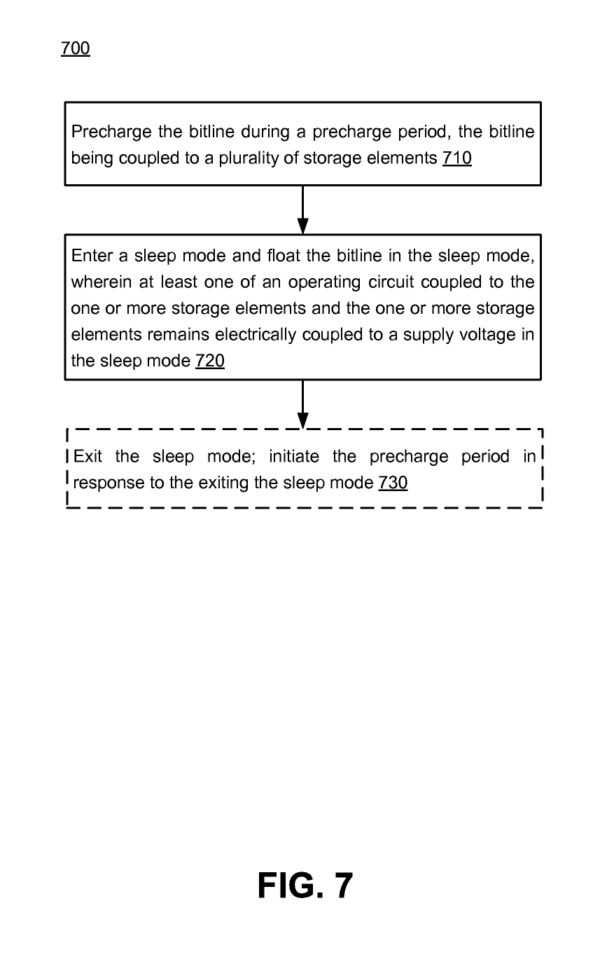

FIG. 7 is a flowchart 700 of the operations of a memory having a sleep mode. The steps drawn in dotted lines may be optional. At 710, the bitline is precharged during a precharge period. The bitline is coupled to a plurality of storage elements. At 720, a sleep mode is entered, and the bitline floats in the sleep mode. At least one of an operating circuit coupled to the one or more storage elements and the one or more storage elements remains electrically coupled to a supply voltage in the sleep mode. At 730, the sleep mode is exited. The precharge period is initiated in response to the exiting the sleep mode. Examples of these operations are described in association with FIGS. 5 and 6.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The various aspects of this disclosure are provided to enable one of ordinary skill in the art to practice the present invention. Various modifications to exemplary embodiments presented throughout this disclosure will be readily apparent to those skilled in the art, and the concepts disclosed herein may be extended to other magnetic storage devices. Thus, the claims are not intended to be limited to the various aspects of this disclosure, but are to be accorded the full scope consistent with the language of the claims. All structural and functional equivalents to the various components of the exemplary embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A memory, comprising:
one or more storage elements;
a bitline coupled to the one or more storage elements;
a precharge circuit configured to precharge the bitline during a precharge period and float the bitline during a sleep mode; and
an operating circuit coupled to the one or more storage elements, wherein at least one of the operating circuit and the one or more storage elements is configured to remain electrically coupled to a supply voltage in the sleep mode,
wherein an initiation of the precharge period immediately follows an exiting of the sleep mode.

2. The memory of claim 1, wherein the precharge circuit is configured to precharge the bitline in response to a precharge trigger.

3. The memory of claim 2, wherein the precharge circuit comprises a pull up device configured to precharge the bitline in response to the precharge trigger and one or more logic elements configured to remove the precharge trigger from the pull up device during the sleep mode.

4. The memory of claim 3, wherein the pull up device comprises a p-channel transistor having a gate, and wherein the one or more logic elements are configured to OR the precharge trigger with a sleep mode signal and provide a result to the gate of the p-channel transistor.

5. The memory of claim 1, wherein the bitline comprises a local bitline coupled directly to the one or more storage elements.

6. The memory of claim 1, wherein the bitline comprises a global bitline coupled indirectly to the one or more storage elements.

7. A method for operating a memory, comprising:
precharging a bitline during a precharge period, the bitline being coupled to one or more storage elements;
entering a sleep mode and floating the bitline in the sleep mode, wherein at least one of an operating circuit coupled to the one or more storage elements and the one or more storage elements remains electrically coupled to a supply voltage in the sleep mode;
exiting the sleep mode; and
initiating the precharge period immediately following the exiting of the sleep mode.

8. The method of claim 7, wherein the precharging the bitline is in response to a precharge trigger.

9. (canceled)

10. A memory, comprising:
a bitline;
means for storing one or more values, wherein the means for storing is coupled to the bitline;
means for precharging the bitline during a precharge period and floating the bitline during a sleep mode; and
means for operating the means for storing, wherein at least one of the means for operating and the means for storing being configured to remain electrically coupled to a supply voltage in the sleep mode.

11. The memory of claim 10, wherein the means for precharging is configured to precharge the bitline in response to a precharge trigger.

12. The memory of claim 11, wherein the means for precharging comprises
a pull up device configured to precharge the bitline in response to the precharge trigger; and
means for removing the precharge trigger from the pull up device during the sleep mode.

13. The memory of claim 12, wherein the pull up device comprises a p-channel transistor having a gate, and wherein the means for removing is configured to OR the precharge trigger with a sleep mode signal and provide a result to the gate of the p-channel transistor.

14. The memory of claim 10, wherein the bitline comprises a local bitline coupled directly to the means for storing.

15. The memory of claim 10, wherein the bitline comprises a global bitline coupled indirectly to the means for storing.
